(19) United States
(12) Patent Application Publication
(10) Pub. No.: US 2026/0206471 A1
(43) Pub. Date: Jul. 16, 2026

(54) DISPLAY MODULE, METHOD OF MANUFACTURING THE DISPLAY MODULE AND ELECTRONIC DEVICE INCLUDING THE DISPLAY MODULE

(71) Applicant: Samsung Display Co., Ltd., Yongin-Si (KR)

(72) Inventor: SIKWANG KIM, Yongin-si (KR)

(21) Appl. No.: 19/362,478

(22) Filed: Oct. 20, 2025

(30) Foreign Application Priority Data
Jan. 14, 2025 (KR) 10-2025-0005250

(51) Int. Cl. H10K 59/80; H10K 59/12; H10K 59/122; H10K 59/65

(52) U.S. Cl. CPC H10K 59/879; H10K 59/1201; H10K 59/122; H10K 59/65; H10K 59/873

(57) ABSTRACT

A display module includes a light-emitting diode, an encapsulation layer, a high-refraction unit, a medium-refraction unit, and a low-refraction unit. The light-emitting diode emits light. The high-refraction unit is disposed on the encapsulation layer. The high-refraction unit includes a first side forming a first angle with a plane parallel to an upper surface of the encapsulation layer. The high-refraction unit has a first refractive index. The medium-refraction unit is disposed on the high-refraction unit. The medium-refraction unit includes a second side forming a second angle with the plane parallel to the upper surface of the encapsulation layer, the second angle greater than the first angle. The medium-refraction unit has a second refractive index smaller than the first refractive index. The low-refraction unit is disposed on the medium-refraction unit and has a third refractive index smaller than the second refractive index.

### CROSS-REFERENCE TO RELATED APPLICATIONS

This application claims priority to and benefits of Korean Patent Application No. 10-2025-0005250 under 35 U.S.C § 119, filed on January 14, 2025, in the Korean Intellectual Property Office, the contents of which are incorporated herein in its entirety by reference.

### BACKGROUND

### 1. Technical Field

The present disclosure relates to a display module, a method of manufacturing the display module, and an electronic device including the display module.

### 2. Description of the Related Art

A user of an electronic device may view a screen from a front of a display module. Accordingly, front light emitted from the display module may be visible to user’s eyes. Therefore, it may be beneficial to increase luminance of the front light to improve performance of the display module.

In another case, due to diversification of a structure of an electronic device, side light emitted from the display module may be visible to user’s eyes. For example, an edge of a display module, such as an edge display, may include a curved surface. In addition, side light emitted from an edge portion of an edge display may be visible to user’s eyes.

In addition, a foldable display may have a bent state in addition to an opened or folded state. Furthermore, one side of the foldable display in a bent state may face a user, and another side may face above and be disposed on, for example, a desk. Side light emitted from the other side may be visible to user’s eyes while front light emitted from the one side of the foldable display is visible to user’s eyes.

As a result, due to diversification of a structure of an electronic device, side light may be visible to user’s eyes. Therefore, it may be beneficial to also increase luminance of side light to improve a display module.

### SUMMARY

Embodiments of the present disclosure provide a display module that includes a refraction layer, including a high-refraction unit, a medium-refraction unit, and a low-refraction unit, having improved luminance of front light and side light through refraction of light from a side of the high-refraction unit and a side of the medium-refraction unit. Embodiments of the present disclosure also provide a method of manufacturing the display module and an electronic device including the display module.

A display module according to an embodiment an embodiment of the present disclosure may include a base member, a light-emitting diode, an encapsulation layer, a high-refraction unit, a medium-refraction unit and a low-refraction unit. The light-emitting diode may be disposed on the base member and configured to emit light. The encapsulation layer may seal off the light-emitting diode. The high-refraction unit may be disposed on the encapsulation layer. The high-refraction unit may include a first side surface forming a first angle with a plane parallel to an upper surface of the encapsulation layer. The high-refraction unit may have a first refractive index. The medium-refraction unit may be disposed on the high-refraction unit. The medium-refraction unit may include a second side surface forming a second angle with the surface parallel to the upper surface of the encapsulation layer, the second angle greater than the first angle. The medium-refraction unit may have a second refractive index smaller than the first refractive index. The low-refraction unit may be disposed on the medium-refraction unit and have a third refractive index smaller than the second refractive index.

In an embodiment an embodiment of the present disclosure, the medium-refraction unit may cover the high-refraction unit. The low-refraction unit may cover the medium-refraction unit.

In an embodiment an embodiment of the present disclosure, the high-refraction unit, the medium-refraction unit and the low-refraction unit may overlap with the light-emitting diode.

In an embodiment an embodiment of the present disclosure, the high-refraction unit, the medium-refraction unit and the low-refraction unit may make contact with a disposition plane.

In an embodiment an embodiment of the present disclosure, the first refractive index may be greater than or equal to 1.6 and less than or equal to 1.9. The second refractive index may be greater than 1.5 and less than 1.6. The third refractive index may be greater than or equal to 1.2 and less than or equal to 1.5.

In an embodiment an embodiment of the present disclosure, the first angle may be greater than or equal to 60 degrees and smaller than or equal to 70 degrees. The second angle may be greater than or equal to 88 degrees and smaller than or equal to 90 degrees.

In an embodiment an embodiment of the present disclosure, an upper surface of the high-refraction unit and the disposition plane may be spaced apart by a first vertical distance. An upper surface of the medium-refraction unit and the disposition plane may be spaced part by a second vertical distance, which is 1.5 times or more and 2.7 times or less of the first vertical distance.

In an embodiment an embodiment of the present disclosure, a pixel defining film may be further included. The pixel defining film may include an inner surface for definition of an opening. In a center of the opening, a line extending in a direction perpendicular to the upper surface of the encapsulation layer may be defined as a pixel axis. The inner surface may be spaced apart from the pixel axis by a first distance. One side of the high-refraction unit may be spaced apart from the pixel axis by a second distance equal to or greater than the first distance. One side of the medium-refraction unit may be spaced apart from the pixel axis by a third distance greater than the second distance.

In an embodiment an embodiment of the present disclosure, the second distance may be greater than or equal to 1 times and less than or equal to 1.11 times of the first distance.

In an embodiment an embodiment of the present disclosure, the third distance may be greater than or equal to 1.65 times and less than or equal to 2.70 times of the first distance.

In an embodiment an embodiment of the present disclosure, an upper inorganic insulating layer and an upper input sensor electrode may be further included. The upper inorganic insulating layer may be disposed between the encapsulation layer and the refraction layer. The upper input sensor electrode may be disposed on the upper inorganic insulating layer.

In an embodiment an embodiment of the present disclosure, a lower inorganic insulating layer and a lower input sensor electrode may be further included. The lower inorganic insulating layer may be disposed between the encapsulation layer and the upper inorganic insulating layer. The lower input sensor electrode may be disposed between the lower inorganic insulating layer and the upper inorganic insulating layer.

An electronic device according to an embodiment an embodiment of the present disclosure may include a window member and a display module. The window member may include a display surface. The display module may be configured to emit light on the window member. The display module may include a base member, a plurality of light-emitting diodes, an encapsulation layer, a high-refraction unit, a medium-refraction unit, and a low-refraction unit. The plurality of light-emitting diodes may be disposed on the base member and each configured to emit light. The encapsulation layer may seal off the plurality of light-emitting diodes. The high-refraction unit may be disposed on the encapsulation layer. The high-refraction unit may include a first side surface having a first side surface forming a first angle with a plane parallel to an upper surface of the encapsulation layer. The high-refraction unit may have a first refractive index. The medium-refraction unit may be disposed on the high-refraction unit. The medium-refraction unit may include a second side surface forming a second angle with the plane parallel to the upper surface of the encapsulation layer, the second angle greater than the first angle. The medium-refraction unit may have a second refractive index smaller than the first refractive index. The low-refraction unit may be disposed on the medium-refraction unit. The low-refraction unit may have a third refractive index smaller than the second refractive index.

In an embodiment an embodiment of the present disclosure, the medium-refraction unit may cover the high-refraction unit. The low-refraction unit may cover the medium-refraction unit. The high-refraction unit, the medium-refraction unit and the low-refraction unit may overlap with at least any one of the plurality of light-emitting diodes.

In an embodiment an embodiment of the present disclosure, the high-refraction unit, the medium-refraction unit and the low-refraction unit may make contact with a disposition plane.

In an embodiment an embodiment of the present disclosure, the low-refraction unit may include a pressure-sensitive adhesive. The low-refraction unit may have the display module coupled to another component.

In an embodiment an embodiment of the present disclosure, the display surface may include a first region and a second region. The first region may allow penetration of light emitted by a portion of the plurality of light-emitting diodes. The second region may allow penetration of light emitted by another portion of the plurality of light-emitting diodes. The high-refraction unit, the medium-refraction unit and the low-refraction unit may be disposed to overlap with the second region. A luminance of light emitted at a viewing angle of 45 degrees from the second region may be greater than a luminance of light emitted at a viewing angle of 45 degrees from the first region.

In an embodiment an embodiment of the present disclosure, the first region may be positioned on a flat plane. The second region may be positioned on a curved plane.

In an embodiment an embodiment of the present disclosure, a camera unit may be further included. The camera unit may be configured to receive light. A folded mode in which a device is folded with respect to a folding axis and an open mode in which a device is opened with respect to the folding axis are possible. The first region may be positioned in one side relative to the folding axis. The second region may be positioned in another side relative to the folding axis. The camera unit may overlap with the first region, but not with the second region, in the open mode.

A method of manufacturing a display module according to an embodiment an embodiment of the present disclosure may include preparing, forming a high-refraction unit, forming a medium-refraction unit, and forming a low-refraction unit. In the preparing, a display panel including a base member, a light-emitting diode disposed on the base member and an encapsulation layer sealing off the light-emitting diode may be prepared. In the forming a high-refraction unit, a high-refraction unit disposed on the encapsulation layer, including first side forming a first angle with a plane parallel to an upper surface of the encapsulation layer, and having a first refractive index may be formed. In the forming a medium-refraction unit, a medium-refraction unit disposed on the high-refraction unit, including a second side forming a second angle with the plane parallel to the upper surface of the encapsulation layer, the second angle greater than the first angle, and having a second refractive index smaller than the first refractive index may be formed. In the forming a low-refraction unit, a low-refraction unit disposed on the medium-refraction unit and having a third refractive index smaller than the second refractive index may be formed.

According to an embodiment an embodiment of the present disclosure, the present disclosure may provide a display module including a refraction layer including a high-refraction unit, a medium-refraction unit, and a low-refraction unit to improve luminance of front light and side light, a method of manufacturing the display module, and an electronic device including the display module.

### BRIEF DESCRIPTION OF THE DRAWINGS

These or other features will become apparent and more readily appreciated from the following description of the embodiments, taken in conjunction with the accompanying drawings in which:

FIG. 1A illustrates an electronic device according to an embodiment of the present disclosure;

FIG. 1B is a cross-sectional view of a display surface of an electronic device according to an embodiment of the present disclosure;

FIG. 2 is a block diagram of an electronic device according to an embodiment of the present disclosure;

FIG. 3 is a cross-sectional view of an electronic device according to an embodiment of the present disclosure;

FIG. 4 is a plan view of a display panel according to an embodiment of the present disclosure;

FIG. 5 is an equivalent circuit diagram of a pixel according to an embodiment of the present disclosure;

FIG. 6 is a timing diagram of a light-emission control signal and scan signals applied to the pixel shown in FIG. 5;

FIG. 7 is a cross-sectional view of a display module according to an embodiment of the present disclosure;

FIG. 8 illustrates a light path in a cross-sectional view of a display module according to an embodiment of the present disclosure;

FIG. 9 is a plan view of any one of a plurality of pixels according to an embodiment of the present disclosure;

FIG. 10 is a flow chart of a method of manufacturing a display module according to an embodiment of the present disclosure;

FIGS. 11A, 11B, 11C, 11D, 11E and 11F are cross-sectional views of a display module as a method of manufacturing the display module proceeds through a series of steps according to an embodiment of the present disclosure;

FIG. 12 is a cross-sectional view of a display module according to an embodiment of the present disclosure;

FIG. 13 is a plan view of any one of a plurality of pixels according to an embodiment of the present disclosure;

FIG. 14 is a cross-sectional view of a display module according to an embodiment of the present disclosure;

FIG. 15 is a cross-sectional view of an electronic device according to an embodiment of the present disclosure;

FIG. 16A is a cross-sectional view of an electronic device according to an embodiment of the present disclosure;

FIG. 16B is a cross-sectional view of a display module according to an embodiment of the present disclosure;

FIGS. 17A, 17B and 17C, are illustrations of a foldable electronic device according to an embodiment of the present disclosure; and

FIG. 18 illustrates electronic devices according to embodiments of the present disclosure.

### DETAILED DESCRIPTION

References will now be made in detail to embodiments, which are illustrated in the accompanying drawings, where like reference numerals refer to like elements throughout. The embodiments may have a variety of forms and permutations, but the present disclosure shall by no means be construed as being limited to the described embodiments. Rather, the present disclosure shall be construed to encompass all forms, permutations, equivalents and substitutes covered by the technical ideas and scope of the present disclosure. Accordingly, the embodiments are merely described below, by referring to the figures, to explain features of the present disclosure.

Like or identical reference numerals refer to like or identical elements. Moreover, in the accompanying drawings, the thicknesses, ratios, and dimensions of the elements may not be to exact scale and may have been exaggerated for the benefit of effective explanation of the technical features associated with these elements. As such, the present disclosure shall not be restricted to the thicknesses, ratios, dimensions, etc. illustrated in the drawings.

As used herein, the terms “comprise,” “include,” and “have” (as well as their variations such as “comprising”) specify the presence of stated features or components, but do not preclude the presence or addition of one or more other features or components.

As used herein, the word “or” means logical “or” so that, unless the context indicates otherwise, the expression “A, B, or C” means “A and B and C,” “A and B but not C,” “A and C but not B,” “B and C but not A,” “A but not B and not C,” “B but not A and not C,” and “C but not A and not B.”

A display device according to an embodiment may be applicable to various electronic devices. An electronic device according to an embodiment may include the described display device and further include a module or a device having an additional function in addition to the display device.

A term, such as “overlapping,” refers to disposition on a normal direction of a surface of a component without being limited to disposition on or below the surface.

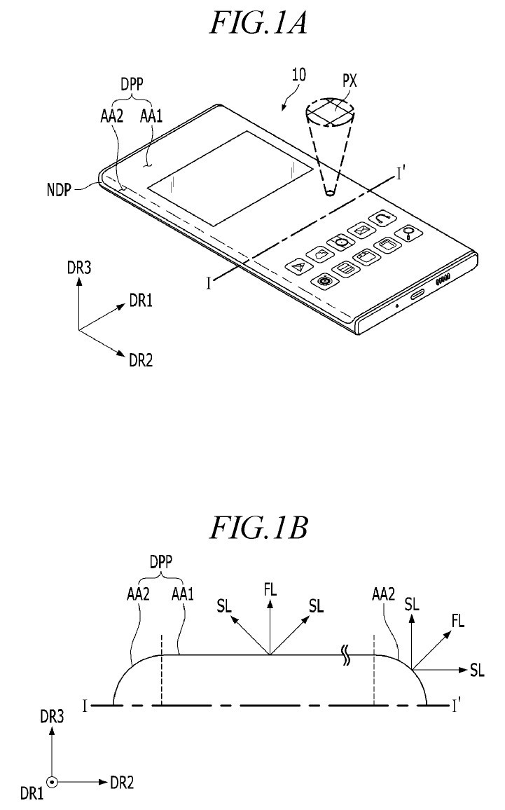

FIG. 1A illustrates an electronic device 10 according to an embodiment of the present disclosure. FIG. 1B is a cross-sectional view of a display surface DPP of an electronic device 10 according to an embodiment of the present disclosure.

Referring to FIG. 1A, and FIG. 1B, the electronic device 10 may have a display surface DPP and a non-display surface NDP defined therein. The electronic device 10 may be a smartphone.

Directions pointed by a first directional axis through a third directional axis DR1, DR2, and DR3 are merely a relative concept, and may be converted into other directions. Hereinafter, the first through the third directions DR1, DR2, and DR3 are directions pointed by the first through the third directional axes DR1, DR2, and DR3, respectively, and described with the same figure references.

The display surface DPP may include a first region AA1 and a second region AA2. A plurality of pixels PX may be disposed to overlap with the display surface DPP. A portion of the display surface DPP may be curved or bent. The display surface DPP may be a surface for displaying an image in an electronic device 10.

Light may be emitted from the display surface DPP. The display surface DPP may allow emission of light emitted from a plurality of light-emitting diodes. A portion of the light emitted from the display surface DPP maybe front light FL emitted in a direction perpendicular to the display surface DPP. Another portion of the light emitted from the display surface DPP may be side light SL emitted in a direction inclined from the direction perpendicular to the display surface DPP by a pre-determined viewing angle. A viewing angle of the side light SL may be 45 degrees.

The first region AA1 may be positioned on a plane defined by a first direction DR1 and a second direction DR2. The first region AA1 may allow emission of light emitted from a portion of the plurality of light-emitting diodes. Light emitted in a third direction DR3 among light emitted from the first region AA1 may be visible to a user of the electronic device 10. Front light FL from the first region AA1 may be emitted in the third direction DR3.

The second region AA2 may be positioned on a curved surface. The second region AA2 may be a curved or bent region. The second region AA2 may be defined on a curved surface positioned at an edge of the first region AA1. There may be two or four second regions AA2 disposed at an edge of the first region AA1 to face each other. In addition, the second region may surround the first region AA1.

The second region AA2 may allow emission of light emitted from another portion of the light-emitting diodes. Among the light emitted from the second region AA2, light emitted in a third direction DR3 may be visible to a user of the electronic device 10. Side light SL from the second region AA2 may be emitted in the third direction DR3.

There may be no light emitted from a non-display surface NDP. The non-display surface NDP may be a surface where non image is displayed in the electronic device 10.

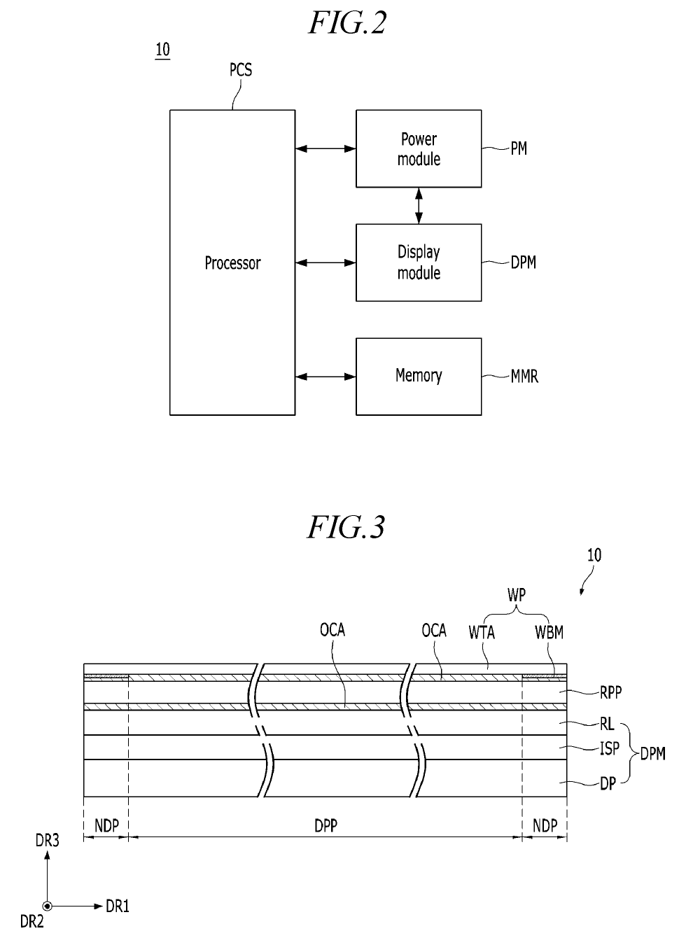

FIG. 2 is a block diagram of an electronic device 10 according to an embodiment of the present disclosure.

Referring to FIG. 2, an electronic device 10 according to an embodiment of the present disclosure may include a display module DPM, a processor PCS, a memory MMR, and a power module PM.

The processor may include at least one of a central processing unit (CPU), an application processor (AP), a graphic processing unit (GPU), a communication processor (CP), an image signal processor (ISP), and a controller. The processor may be implemented by more than one processor.

The memory MMR may store data necessary for operations of the processor PCS or the display module DPM. When the processor PCS executes an application stored in the memory MMR, an image data signal or an input control signal may be transferred to the display module DPM, which may then process the received signals and output image information through a display screen.

The power module PM may include a power supply module, such as a power adapter or a battery device, and a power conversion module configured to convert the power supplied by the power supply module into power required for the operation of the electronic device 10.

At least one of the above-described components of the electronic device 10 may be included within the display device DD according to the above-described embodiments. Additionally, certain individual modules included functionally within a single module may be provided within the display device while other individual modules may be provided outside the display device. For instance, the display device may include the display module DPM, and the processor PCS, memory MMR, and power module PM may be provided as other devices within the electronic device 10 but not within the display device.

FIG. 3 is a cross-sectional view of an electronic device 10 according to an embodiment of the present disclosure.

Referring to FIG. 3, an electronic device 10 may include a display module DPM, a reflection protection member RPP, a window member WP, and a plurality of adhesives OCA. In FIG. 3, a curved or bent configuration of a portion of the display surface DPP is not particularly illustrated, and an illustration of a lamination structure of the electronic device 10 is simplified.

The display module DPM may include a display panel DP, an input sensor unit ISP, and a refraction layer RL. The display module DPM may emit light on the window member WP.

The display panel DP may emit light. The display panel DP may be a light-emitting display panel. The display panel DP may be an organic light-emitting display panel, a quantum dot light-emitting display panel, or a micro light-emitting display panel. The display panel DP may include a plurality of light-emitting diodes.

The input sensor unit ISP may be disposed on the display panel DP. The input sensor unit ISP may be configured to obtain a coronation information of an external input. Particularly, at least any one of a mutual-capacitance type input sensor, a self-capacitance type input sensor, a resistive film type input sensor, an optical sensor, an electromagnetic resonance type input sensor, an ultrasound type input sensor, and an infrared light input sensor may be utilized as the input sensor unit ISP.

The refraction layer RL may be disposed on the input sensor unit ISP. In the refraction layer RL, light emitted from the display panel DP may be refracted. The refraction layer RL may have light refracted to increase luminance of front light and side light.

Although FIG. 3 illustrates that the refraction layer RL overlaps with the entire display surface DPP, the refraction layer RL may overlap with a portion of the display surface DPP. For example, the fraction layer RL may overlap only with the second region AA2 shown in FIG. 1A and FIG. 1B. Accordingly, luminance of side light emitted from the second region AA2 may be increased.

The reflection protection member RPP may be disposed on the refraction layer RL. In addition, the reflection protection member RPP may reduce a reflectivity of external light incident from above of the window member WP. The reflection protection member RPP according to an embodiment of the present disclosure may include a retarder, a polarizer, and a plurality of color filters.

The window member WP may be disposed on the reflection protection member RPP. The window member WP may include a light-transmitting part WTA and a light-blocking part WBM.

The light-transmitting part WTA may include a display surface DPP. The light-transmitting part WTA may include glass or synthetic resin. The light-transmitting part WTA may not be limited to single layer. The light-transmitting part WTA may include two or more films attached by an adhesive member.

The display surface DPP may be a portion of an upper surface of the light-transmitting part WTA. The display surface DPP may be a portion of the upper surface of the light-transmitting part WTA not overlapping with the light-blocking part WBM.

The light-blocking part WBM may include the non-display surface NDP. The light-blocking part WBM may partially overlap with the light-transmitting part WTA. The light-blocking part WBM may be disposed on a rear surface of the light-transmitting part WTA.

The non-display surface NDP may be an upper surface of the light-blocking part WBM.

A portion of the plurality of adhesives OCA may be disposed between the refraction layer RL and the reflection protection member RPP. Due to the portion of the plurality of adhesives OCA, the refraction layer RL and the reflection protection member RPP may be attached.

Another portion of the plurality of adhesives OCA may be disposed between the reflection protection member RPP and the window member WP. Due to the other portion of the plurality of adhesives OCA, the reflection protection member RPP and the window member WP may be attached.

A position of the plurality of adhesives OCA is not limited to thereto. The plurality of adhesives OCA may be further disposed between the display panel DP and the input sensor unit ISP. In addition, at least a portion of the plurality of adhesives OCA may be omitted.

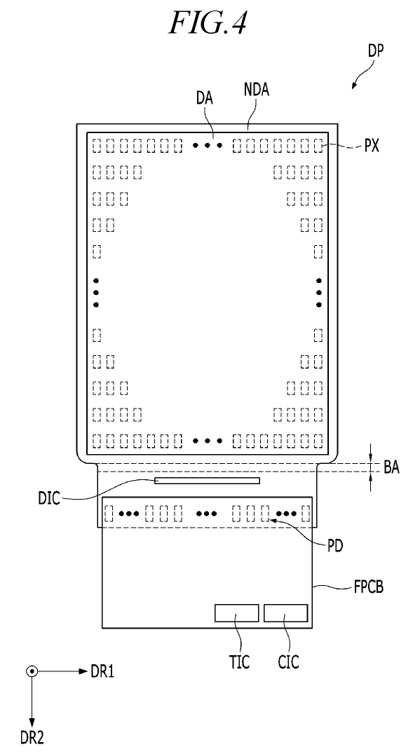

FIG. 4 is a plan view of a display panel DP according to an embodiment of the present disclosure.

The display panel DP may have a display region DA and a non-display region NDA defined therein. The non-display region NDA may be defined along an outer periphery of the display region DA. The display region DA may correspond to the display surface DPP of the electronic device 10 shown in FIG. 1A and FIG. 1B. The non-display region NDA may correspond to the non-display surface NDP of the electronic device 10 shown in FIG. 1A and FIG. 1B.

The display panel DP may include a plurality of pixels PX, a data driving circuit DIC, a plurality of pads PD, a flexible printed circuit board FPCB, an input sensor driving circuit TIC, and a control driving circuit CIC.

The data driving circuit DIC may be electrically connected to the pixels PX of the display region DA to provide a data signal to the pixels PX.

The input sensor driving circuit TIC and the control driving circuit CIC may be mounted in the flexible printed circuit board FPCB and receive an electric signal from the plurality of pads PD.

Through input sensor circuit ISC, the input sensor driving circuit TIC may utilize the plurality of pads PD to process a signal corresponding to a change in a current by a user’s touch applied to the display region DA or a signal corresponding to a pressure applied from outside.

The control driving circuit CIC may be a circuit configured to control at least any one of the data driving circuit DIC and the input sensor driving circuit TIC.

A bending region BA portion of the display panel DP may be bendable.

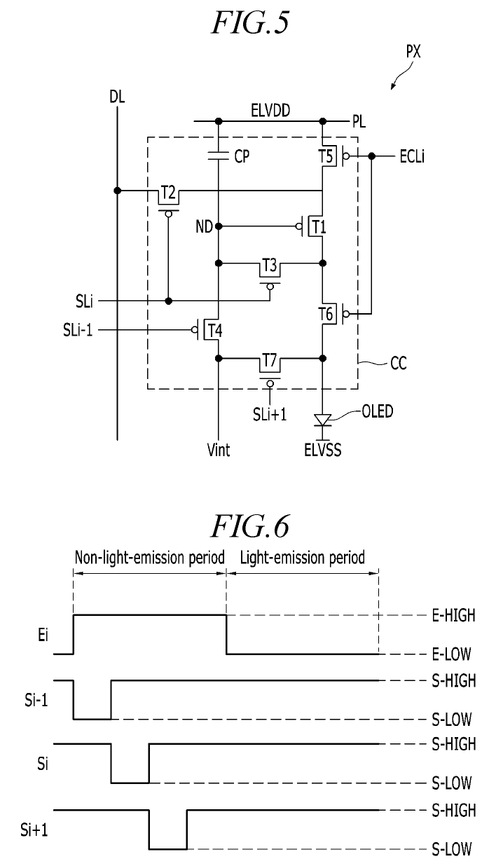

FIG. 5 is an equivalent circuit diagram of a pixel PX according to an embodiment of the present disclosure. FIG. 6 is a timing diagram of a light-emission control signal Ei and scan signals Si-1, Si, and Si+1 applied to the pixel PX shown in FIG. 5.

Referring to FIG. 5, a pixel PX connected to an i-th scan line SLi and an i-th light-emission control line ECLi.

The pixel PX may include an organic light-emitting diode OLED and a pixel circuit CC. The pixel circuit CC may include a plurality of transistors T1 to T7 and a capacitor CP. The pixel circuit CC may be configured to respond to a data signal to control an amount of current flowing through the organic light-emitting diode OLED.

The organic light-emitting diode OLED may be configured to respond to an amount of current provided from the pixel circuit CC to emit light with a determined luminance. To that end, a level of a first power ELVDD may be set higher than a level of a second power ELVSS.

Each of the plurality of transistors T1 to T7 may include an input electrode (or a source electrode), an output electrode (or a drain electrode), and a control electrode (or a gate electrode). In the present disclosure, for convenience, one of the input electrode and the output electrode may be referred to as a first electrode, and the other may be referred to as a second electrode.

A first electrode of a first transistor T1 is connected to the first power ELVDD via a fifth transistor T5, and a second electrode is connected to an anode electrode of an organic light-emitting diode OLED via a sixth transistor T6. The first transistor T1 may be referred to as a driving transistor in this specification.

The first transistor T1 is configured to control the amount of current flowing through the organic light-emitting diode OLED in response to a voltage applied to the control electrode.

A second transistor T2 is connected between a data line DL and the first electrode of the first transistor T1. In addition, a control electrode of the second transistor T2 is connected to the i-th scan line SLi. When the i-th scan signal Si is provided to the i-th scan line SLi, the second transistor T2 is turned on to electrically connect the data line DL and the first electrode of the first transistor T1.

A third transistor T3 is connected between the second electrode and the control electrode of the first transistor T1. A control electrode of the third transistor T3 is connected to the i-th scan line SLi. When the i-th scan signal Si is provided to the i-th scan line SLi, the third transistor T3 is turned on to electrically connect the second electrode and the control electrode of the first transistor T1. Accordingly, when the third transistor T3 is turned on, the first transistor T1 is connected in the form of a diode.

A fourth transistor T4 is connected between a node ND and an initialization power generation unit (not shown). In addition, a control electrode of the fourth transistor T4 is connected to an (i-1)-th scan line SLi-1. When an (i-1)-th scan signal Si-1 is provided to the (i-1)-th scan line SLi-1, the fourth transistor T4 is turned on to provide an initialization voltage Vint to the node ND.

A fifth transistor T5 is connected between a power line PL and the first electrode of the first transistor T1. A control electrode of the fifth transistor T5 is connected to the i-th light-emission control line ECLi.

A sixth transistor T6 is connected between the second electrode of the first transistor T1 and the anode electrode of the organic light-emitting diode OLED. In addition, a control electrode of the sixth transistor T6 is connected to the i-th light-emission control line ECLi.

A seventh transistor T7 is connected between the initialization power generation unit (not shown) and the anode electrode of the organic light-emitting diode OLED. In addition, a control electrode of the seventh transistor T7 is connected to an (i+1)-th scan line SLi+1. When an (i+1)-th scan signal Si+1 is provided to the (i+1)-th scan line SLi+1, such seventh transistor T7 is turned on to provide the initialization voltage Vint to the anode electrode of the organic light-emitting diode OLED.

The seventh transistor T7 may improve the black expression capability of the pixel PX. Specifically, when the seventh transistor T7 is turned on, a parasitic capacitor (not shown) of the organic light-emitting diode OLED is discharged. Then, when the black luminance is implemented, the organic light-emitting diode OLED does not emit light due to the leakage current from the first transistor T1, and accordingly, the black expression capability may be improved.

Additionally, in FIG. 5, the control electrode of the seventh transistor T7 is shown to be connected to the (i+1)-th scan line SLi+1, but the present disclosure is not limited to this configuration. In an embodiment of the present disclosure, the control electrode of the seventh transistor T7 may be connected to the i-th scan line SLi or the (i-1)-th scan line SLi-1.

FIG. 5 is Illustrated based on PMOS, but the present disclosure is not limited to this configuration. In an embodiment of the present disclosure, the pixel PX may be composed of NMOS. In an embodiment of the present disclosure, the pixel PX may be composed of a combination of NMOS and PMOS.

The capacitor CP is interposed between the power line PL and the node ND. The capacitor CP is configured to store a voltage corresponding to the data signal. When the fifth transistor T5 and the sixth transistor T6 are turned on, the amount of current flowing through the first transistor T1 may be determined according to the voltage stored in the capacitor CP.

A structure of the pixel PX in the present disclosure is not limited to what is illustrated in FIG. 5. In an embodiment of the present disclosure, the pixel PX may be implemented in various forms for light-emission of the organic light-emitting diode OLED.

Referring to FIG. 6, the light-emitting control signal Ei may have a high level E-HIGH or a low level E-LOW. Each of the scan signals SLi-1, SLi, and SLi+1 may have a high level S-HIGH or a low level S-LOW.

When the light emission control signal Ei has a high level E-HIGH, the fifth transistor T5 and the sixth transistor T6 are turned off. When the fifth transistor T5 is turned off, the power line PL and the first electrode of the first transistor T1 are electrically cut off. When the sixth transistor T6 is turned off, the second electrode of the first transistor T1 and the anode electrode of the organic light-emitting diode OLED are electrically cut off. Accordingly, the organic light-emitting diode OLED does not emit light while the light emission control signal Ei having a high level E-HIGH is provided to the i-th light emission control line ECLi.

Thereafter, when the (i-1)-th scan signal Si-1 provided to the (i-1)-th scan line SLi-1 has a low level S-LOW, the fourth transistor T4 is turned on. When the fourth transistor T4 is turned on, the initialization voltage Vint is provided to the node ND.

When the i-th scan signal Si provided to the i-th scan line SLi has a low level S-LOW, the second transistor T2 and the third transistor T3 are turned on.

When the second transistor T2 is turned on, a data signal is provided to the first electrode of the first transistor T1. Here, since the node ND is initialized to the initialization voltage Vint, the first transistor T1 is turned on. When the first transistor T1 is turned on, a voltage corresponding to the data signal is provided to the node ND. Here, the capacitor CP stores a voltage corresponding to the data signal.

When the (i+1)-th scan signal Si+1 provided to the (i+1)-th scan line SLi+1 has a low level S-LOW, the seventh transistor T7 is turned on.

When the seventh transistor T7 is turned on, the initialization voltage Vint is provided to the anode electrode of the organic light-emitting diode OLED, thereby discharging the parasitic capacitor of the organic light-emitting diode OLED.

When the light emission control signal Ei provided to the light emission control line ECLi has a low level E-LOW, the fifth transistor T5 and the sixth transistor T6 are turned on. When the fifth transistor T5 is turned on, the first power ELVDD is provided to the first electrode of the first transistor T1. When the sixth transistor T6 is turned on, the second electrode of the first transistor T1 and the anode electrode of the organic light-emitting diode OLED are electrically connected. Then, the organic light-emitting diode OLED generates light of a predetermined luminance in response to the amount of supplied current.

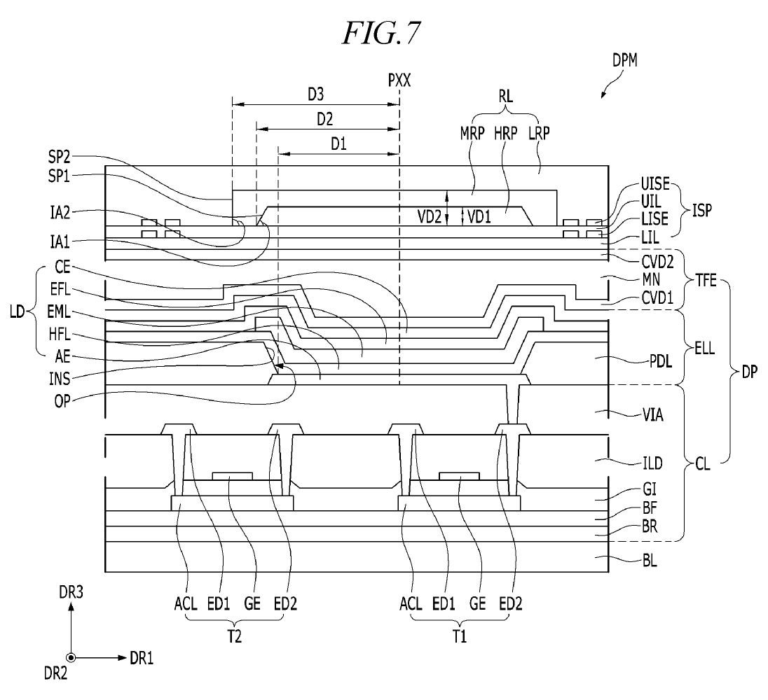

FIG. 7 is a cross-sectional view of a display module DPM according to an embodiment of the present disclosure.

Referring to FIG. 7, the display module DPM may include a base member BL, a display panel DP, an input sensor unit ISP, and a refraction layer RL.

A circuit layer CL may be disposed on the base member BL. That is, other components of the circuit layer CL may be laminated on the base member BL. The base member BL may include an organic layer or an inorganic layer. The organic layer may include an organic material. For example, polyimide may be included. The inorganic layer may include an inorganic material.

The display panel DP may include a circuit layer CL, a light-emitting diode layer ELL and an encapsulation layer TFE. The display panel DP may emit light.

The circuit layer CL may include a barrier layer BR, a buffer layer BF, a gate insulating layer GI, an interlayer insulating layer ILD, a circuit insulating layer VIA, a first transistor T1 and a second transistor T2.

The first transistor T1 and the second transistor T2 may be configured to transfer an electrical signal. In addition, the first transistor T1 and the second transistor T2 may include a plurality of active parts ACL, a plurality of first electrodes ED1, a plurality of control electrodes GE, and a plurality of second electrodes ED2.

The barrier layer BR may be disposed on the base member BL. The barrier layer BR may be configured to prevent penetration of, for example, moisture introduced from outside. The barrier layer BR may include an organic insulating material, such as silicon oxide and silicon nitride.

The buffer layer BF may be disposed on the barrier layer BR. The buffer layer BF may prevent impurities introduced from below from moving above. Accordingly, a component disposed on the buffer layer BF may be protected. The buffer layer BF may include an inorganic material, such as silicon oxide and silicon nitride.

The plurality of active parts ACL may be disposed on the buffer layer BF. The plurality of active parts ACL may include polysilicon or amorphous silicon. Other plurality of active parts ACL may include metal oxide semiconductor. The plurality of active parts ACL may each include a channel region, which is configured to function as a pathway for electrons and holes to travel, and a first ion doping region and a second ion doping region, which are disposed on either side of the channel region.

The gate insulating layer GI may cover the buffer layer BF and the plurality of active parts ACL. The gate insulating layer GI may include an organic film or an inorganic film. The gate insulating layer GI may include a plurality of inorganic thin films. The plurality of inorganic thin films may include a silicon nitride layer and a silicon oxide layer.

The plurality of control electrodes GE may be disposed on the buffer layer BF. The plurality of control electrodes GE may overlap with the plurality of active parts ACL. In addition, the plurality of control electrodes GE may include molybdenum (Mo).

The interlayer insulating layer ILD may cover the gate insulating layer GI and the plurality of control electrodes GE. The interlayer insulating layer ILD may include an organic film or an inorganic film. The interlayer insulating layer ILD may include a plurality of inorganic thin films or organic thin films. The plurality of inorganic thin films may include a silicon nitride layer and a silicon oxide layer.

The plurality of first electrodes ED1 and the plurality of second electrodes ED2 may be disposed on the interlayer insulating layer ILD. The plurality of first electrodes ED1 and the plurality of second electrodes ED2 may be electrically connected to the plurality of active parts ACL through a plurality of contact holes defined on the interlayer insulating layer ILD. In addition, the plurality of first electrodes ED1 and the plurality of second electrodes ED2 may include metal.

The circuit insulating layer VIA may cover the interlay insulating layer ILD, the plurality of first electrodes ED1 and the plurality of second electrodes ED2. The circuit insulating layer VIA may include an organic film or an inorganic film. The circuit insulating layer VIA may provide a flat surface. In an embodiment, an amount of the circuit insulating layer VIA may be increase as necessary.

The light-emitting diode layer ELL may include a pixel definition film PDL and a light-emitting diode LD. The light-emitting diode ELL may emit light.

The pixel definition film PLD may include an inner surface INS. The pixel definition film PDL may be disposed on a portion of the circuit insulating layer VIA.

The inner surface INS may define an opening OP. In addition, the opening OP may expose the light-emitting diode LD.

The opening OP may define a pixel. In a center of the opening OP, a line extending in a direction perpendicular to an upper surface of the encapsulation layer TFE is defined as a pixel axis PXX. In addition, the inner surface INS may be spaced apart from the pixel axis PXX by a first distance D1. The first distance D1 may be greater than or equal to 4.7 micrometers and smaller than or equal to 9.3 micrometers.

A width of the opening OP may be twice of the first distance D1. The width of the opening OP may be greater than or equal to 9.4 micrometers and smaller than or equal to 18.6 micrometers.

The light-emitting diode LD may emit light. In addition, the light-emitting diode LD may include an anode electrode AE, a hole functional layer HFL, a light-emission layer EML, an electron functional layer EFL and a cathode electrode CE.

The anode electrode AE may be disposed on a portion of the circuit insulating layer VIA. Particularly, the anode electrode AE may be exposed by the opening OP. In addition, the anode electrode AE may be electrically connected to any one of the plurality of second electrodes ED2 through a contact hole defined in the circuit insulating layer VIA. Accordingly, the anode electrode AE may be configured to receive an electric signal from the first transistor T1 and the second transistor T2.

Although FIG. 7 exemplarily illustrates the first transistor T1 and the second transistor T2, structures of the first transistor T1 and the second transistor T2 are not limited thereto. Although FIG. 7 is illustrated as if the first transistor T1 makes direct contact with the anode electrode AE through any one of the plurality of second electrodes ED2, this is due to the cross-sectional view, and in reality, the first transistor T1 may be connected to the anode electrode AE through another transistor. However, the present disclosure is not limited thereto, and in an embodiment of the present disclosure, the first transistor T1 may make direct contact with the anode electrode AE through any one of the plurality of second electrodes ED2.

The hole functional layer HFL may be disposed on the anode electrode AE. The hole functional layer HFL may be configured to support transfer of a hole generated from the anode electrode AE. For example, the hole functional layer HFL may be configured to more readily receive a hole injected from the first anode electrode AE and facilitate the transfer of the hole. The hole functional layer HFL may have a multi-layer structure. For example, a hole injection layer (not shown) and a hole transfer layer (not shown) may be further included.

The light-emission layer EML may be disposed on the hole functional layer HFL. The light-emission layer EML may emit light. The light-emission layer EML may include, for example, an organic light-emitting material or a quantum dot. Accordingly, the light-emitting diode LD may be an organic light-emitting diode or a quantum dot light-emitting diode.

The electron functional layer EFL may be disposed on the light-emission layer EML. The electron functional layer EFL may be configured to support transfer of an electron generated from the cathode electrode CE. For example, the electron functional layer EFL may be configured to more readily receive an electron injected from the cathode electrode CE and facilitate the transfer of the electron. The electron functional layer EFL may have a multi-layer structure. For example, an electron injection layer (not shown) and an electron transfer layer (not shown) may be further included.

The cathode electrode CE may be disposed on the electron functional layer EFL. The cathode electrode CE has a low resistance, and thus current may readily flow.

The encapsulation layer TFE may be configured to seal off the light-emitting diode LD and protect the light-emitting diode LD from external oxygen or moisture. The encapsulation layer TFE may include a first inorganic encapsulation layer CVD1, an encapsulation organic layer MN, and a second inorganic encapsulation layer CVD2.

While the encapsulation layer TFE in FIG. 7 is illustrated to include two inorganic encapsulation layers CVD1, and CVD2, and one organic encapsulation layer MN, the present disclosure is not limited to this configuration. For example, the encapsulation layer TFE may include three inorganic encapsulation layers and two organic encapsulation layers, in which case the inorganic encapsulation layers and the organic encapsulation layers may be alternately laminated.

The input sensor unit ISP may include a lower inorganic insulating layer LIL, a lower input sensor electrode LISE, an upper inorganic insulating layer UIL, and an upper input sensor electrode UISE. The input sensor unit ISP shown in FIG. 7 may include a mutual-capacitance type input sensor.

The lower inorganic insulating layer LIL may be disposed on the encapsulation layer TFE. The lower inorganic insulating layer LIL may have a single layer structure or a multi-layer structure and include an inorganic material or a composite material. The inorganic material may include at least one of aluminum oxide, titanium oxide, silicon oxide, silicon oxynitride, zirconium oxide, and hafnium oxide. In an embodiment, the lower inorganic insulating layer LIL may be replaced with an organic insulating layer. In addition, the lower inorganic insulating layer LIL may be omitted.

The lower input sensor electrode LISE may be disposed on the lower inorganic insulating layer LIL. The lower input sensor electrode LISE may include a metallic layer or a transparent electrode. The metallic layer may include molybdenum, silver, titanium, copper, aluminum, and an alloy thereof. The transparent electrode may include a transparent conductive oxide, such as ITO (indium tin oxide), IZO (indium zinc oxide), ZnO (zinc oxide), or ITZO (indium tin zinc oxide).

The upper inorganic insulating layer UIL may be disposed on the lower input sensor electrode LISE. The upper inorganic insulating layer UIL may cover the lower input sensor electrode LISE. A detailed configuration of the upper inorganic insulating layer UIL may be same as that of the lower inorganic insulating layer LIL.

The upper input sensor electrode UISE may be disposed on the upper inorganic insulating layer UIL. A detailed configuration of the input sensor electrode UISE may be same as that of the lower input sensor electrode LISE.

The refraction layer RL may include a high-refraction unit HRP, a medium-refraction unit MRP, and a low-refraction unit LRP. Light may be refracted in the refraction layer RL.

The high-refraction unit HRP may be disposed on the upper inorganic insulating layer UIL. A plane of disposition of the high-refraction unit HRP may be defined as a disposition plane. A lower surface of the high-refraction unit HRP may make contact with an upper surface of the upper inorganic insulating layer UIL. The high-refraction unit HRP may overlap with the light-emitting diode LD.

The high-refraction unit HRP may include a first side SP1 forming a first angle IA1 with a plane parallel to an upper surface of the encapsulation layer TFE. In FIG. 7, an upper surface of the inorganic insulating layer UIL may be parallel to the upper surface of the encapsulation layer TFE. The first angle IA1 may be greater than or equal to 60 degrees and smaller than or equal to 70 degrees. In a cross-sectional view, the high-refraction unit HRP may have an isosceles trapezoid shape.

The high-refraction unit HRP may have a first refractive index. The first refractive index may be greater than or equal to 1.6 and smaller than or equal to 1.9. For example, the first refractive index may be 1.63.

An upper surface of the high-refraction unit HRP and the disposition plane may be spaced apart by a first vertical distance VD1. The first vertical distance VD1 may be a distance between a lower surface of the high-refraction unit HRP and an upper surface of the high-refraction unit HRP. The first vertical distance VD1 may be, for example, greater than or equal to 1.5 micrometers and smaller than or equal to 2 micrometers.

One side of the high-refraction unit HRP may be spaced apart from the pixel axis PXX by a second distance D2 greater than or equal to the first distance D1. The one side of the high-refraction unit HRP may be an edge of the lower surface of the high-refraction unit HRP. The second distance D2 may be, for example, greater than or equal to 4.7 micrometers and smaller than or equal to 9.8 micrometers. In addition, a difference between the second distance D2 and the first distance D1 may be greater than or equal to 0 micrometers and smaller than or equal to 0.5 micrometers.

The high-refraction unit HRP may include an acrylic organic material. For example, the high-refraction unit HRP may include poly acrylate. The high-refraction unit HRP may further include a refractive index adjusting agent. The refractive index adjusting agent added in the high-refraction unit HRP may increase a refractive index of the high-refraction unit HRP. The refractive index adjusting agent included in the high-refraction unit HRP may be a multifunctional monomer.

The medium-refraction unit MRP may be disposed on the high-refraction unit HRP. The medium-refraction unit MRP may cover the high-refraction unit HRP. A lower surface of the medium-refraction unit MRP may make contact with the disposition plane. The medium-refraction unit MRP may overlap with the light-emitting diode LD.

The medium-refraction unit MRP may include a second side SP2 forming a second angle IA2 with the plane parallel to the upper surface of the encapsulation layer TFE. The second angle IA2 may be greater than the first angle IA1. The second angle IA2 may be greater than or equal to 88 degrees and smaller than or equal to 90 degrees. In a cross-sectional view, the medium-refraction unit MRP may have an isosceles trapezoid or rectangular shape.

The medium-refraction unit MRP may have a second refractive index. The second refractive index may be smaller than the first refractive index. The second refractive index may be greater than 1.5 and smaller than 1.6. For example, the second refractive index may be 1.54.

An upper surface of the medium-refraction unit MRP and the disposition plane may be spaced apart by a second vertical distance VD2. The second vertical distance VD2 may be a distance between a lower surface of the medium-refraction unit MRP and the upper surface of the medium-refraction unit MRP. The second vertical distance VD2 may be, for example, greater than or equal to 3 micrometers and smaller than or equal to 4 micrometers. The second vertical distance VD2 may be greater than or equal to 1.5 times and less than or equal to 2.7 times of the first vertical distance VD1.

One side of the medium-refraction unit MRP may be spaced apart from the pixel axis PXX by a third distance D3 greater than the second distance D2. The one side of the medium-refraction unit MRP may be an edge of the lower surface of the medium-refraction unit MRP. The third distance D3 may be, for example, greater than or equal to 10.7 micrometers and smaller than or equal to 17.3 micrometers. In addition, a difference between the third distance D3 and the first distance D1 may be greater than or equal to 6 micrometers and smaller than or equal to 8 micrometers.

The medium-refraction unit MRP may include an acrylic organic material. For example, the medium-refraction unit MRP may include polyacrylate. The medium-refraction unit MRP may further include a refractive index adjusting agent. The refractive index adjusting agent added in the medium-refraction unit MRP may adjust a refractive index of the medium-refraction unit MRP.

The low-refraction unit LRP may be disposed on the medium-refraction unit MRP. The low-refraction unit LRP may cover the medium-refraction unit MRP. The low-refraction unit LRP may make contact with the disposition plane. The low-refraction unit LRP may overlap with the light-emitting diode LD.

The low-refraction unit LRP may have a third refractive index. The third refractive index may be smaller than the second refractive index. The third refractive index may be greater than or equal to 1.2 and smaller than or equal to 1.5. For example, the third refractive index may be 1.4.

The low-refraction unit LRP may include an acrylic organic material. For example, the low-refraction unit LRP may include polyacrylate. The low-refraction unit LRP may further include a refractive index adjusting agent. The refractive index adjusting agent added in the low-refraction unit LRP may lower a refractive index of the low-refraction unit LRP. The refractive index adjusting agent included in the low-refraction unit LRP may be hollow silica.

In an embodiment of the present disclosure, the low-refraction unit LRP may include a pressure-sensitive adhesive. The low-refraction unit LRP may be configured to attach the display module DPM with another component.

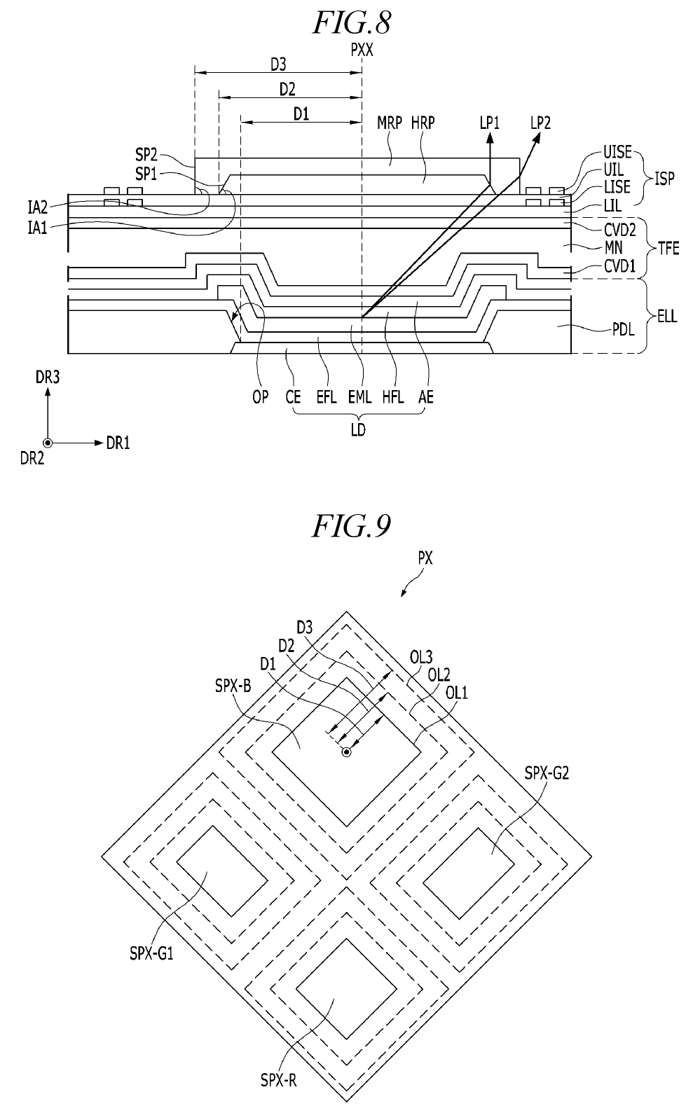

FIG. 8 illustrates a light path in a cross-sectional view of a display module DPM according to an embodiment of the present disclosure.

Referring to FIG. 8, a portion of light emitted from the light-emission layer EML may be emitted along a first light path LP1 or a second light path LP2.

Light emitted from the light-emission layer EML along the first light path LP1 may be side light. The light emitted from the light-emission layer may be refracted by the first side SP1. The light refracted by the first side SP1 may have a low viewing angle. The light refracted by the first side SP1 may be front light.

Therefore, side light may be converted to front light by the first side SP1. Accordingly, luminance of front light may be increased by the first side Sp1. In addition, luminance of side light may be reduced by the first side SP1.

In an embodiment, as described above, the first angle IA1 may be greater than or equal to 60 degrees and smaller than or equal to 70 degrees.

In case that the first angle IA1 is smaller than 60 degrees, an incident angle may be low when light emitted from the light-emission layer EML is incident on the first side SP1. Accordingly, light refracted by the first side SP1 may be less refracted. Therefore, light refracted by the first side SP1 may not face front.

In addition, in case that the first angle IA1 is greater than 70 degrees, an incident angle may be high when light emitted from the light-emission layer EML is incident on the first side SP1. Accordingly, light emitted from the light-emission layer EML may be totally reflected by the first side SP1. Therefore, light may not be refracted by the first side SP1 and may not face front.

Furthermore, as described above, the second distance D2 may be greater than or equal to 1 times and less than or equal to 1.11 times of the first distance D1.

In case that the second distance D2 is less than 1 times the first distance D1, an area of the first side SP1 may become narrower. Therefore, an optical effect by the first side SP1 may be reduced.

In case that the second distance D2 is greater than 1.11 times the first distance D1, light emitted from the light-emission layer EML may have a large incident angle on the first side SP1. Therefore, light refracted by the first side SP1 may be less refracted.

In addition, in case that the second distance D2 is greater than 1.11 times the first distance D1, due to the first side SP1, light emitted from the light-emission layer EML may be prevented from being incident on the second side SP2. Therefore, an optical effect by the second side SP2 may be reduced.

Light emitted from the light-emission layer EML along the second light path LP2 may be side light having a relatively large viewing angle. The side light having a relatively large viewing angle may be totally reflected by the window member WP shown in FIG. 4 and may not be emitted to outside of the electronic device 10.

Light emitted from the light-emission layer EML may be refracted by the second side SP2. The light refracted by the second side SP2 may be side light having a relatively small viewing angle. The side light having a relatively small viewing angle may penetrate the window member WP shown in FIG. 4 to be emitted to outside of the electronic device 10.

Therefore, side light that cannot be emitted to outside of the electronic device 10 may be converted to side light to be emitted to outside of the electronic device 10 by the second side SP2. Accordingly, luminance of side light may be increased by the second side SP2.

In an embodiment, as described above, the second angle IA2 may be greater than or equal to 88 degrees and smaller than or equal to 90 degrees. In case that the second angle IA2 is smaller than 88 degrees, light emitted from the light-emission layer EML may have a large incident angle on the second side SP2. Therefore, light refracted by the second side SP2 may be less refracted.

In addition, the third distance D3 may be greater than or equal to 1.65 times and smaller than or equal to 2.70 times of the first distance D1. In case that the third distance D3 is smaller than 1.65 times the first distance D1, a viewing angle of light emitted from the light-emission layer EML to be refracted by the second side SP2 may be reduced. Therefore, side light that can be emitted to outside of the electronic device 10 even without being refracted by the second side SP2 may be refracted by the second side SP2. Accordingly, effects of increasing luminance of side light by the second side SP2 may be reduced.

In addition, in case that the third distance D3 is smaller than 1.65 times the first distance D1, an area of the second side SP2 may be narrowed. Accordingly, an optical effect by the second side SP2 may be reduced.

In case that the third distance D3 is greater than 2.70 times the first distance D1, light emitted from the light-emission layer EML to be refracted by the second side SP2 may have a large viewing angle. Accordingly, light that cannot be emitted to outside of the electronic device 10 even after refraction by the second side SP2 may be refracted by the second side SP2. Accordingly, effects of increasing luminance of side light by the second side SP2 may be reduced.

FIG. 9 is a plan view of any one of a plurality of pixels PX according to an embodiment of the present disclosure.

Referring to FIG. 9, the plurality of pixels PX may each include a blue sub pixel SPX-B, a red sub pixel SPX-R, a first green sub pixel SPX-G1 and a second green sub pixel SPX-G2. In addition, a plurality of first contour lines OL1, a plurality of second contour lines OL2 and a plurality of third contour lines OL3 may be defined.

The plurality of sub pixels SPX-B, SPX-R, SPX-G1, and SPX-G2 may each emit light of different wavelengths. Alternatively, the sub-pixels SPX-G1, and SPX-G2 may emit light of a same wavelength.

The plurality of sub pixels SPX-B, SPX-R, SPX-G1, and SPX-G2 may each be defined by the opening OP shown in FIG. 7. The plurality of sub pixels SPX-B, SPX-R, SPX-G1, and SPX-G2 may each have a pixel axis PXX, as shown in FIG. 7, defined in its center.

For example, the blue sub pixel SPX-B emit blue light. The red sub pixel SPX-R may emit red light. The first green sub pixel SPX-G1 and the second green sub pixel SPX-G2 may emit green light.

The plurality of first contour lines OL1 may define each shape of the plurality of sub pixels SPX-B, SPX-R, SPX-G1, and SPX-G2. The plurality of first contour lines OL1 may each be substantially defined by a planar shape of the opening OP shown in FIG. 7.

A distance between each of the plurality of first contour lines OL1 and its pixel axis PXX may be a first distance D1. The first distance D1 shown in FIG. 9 may be same as the first distance D1 shown in FIG. 7.

The plurality of second contour lines OL2 may each define a planar shape of the high-refraction unit HRP shown in FIG. 7. The plurality of second contour lines OL2 may each define a shape of the lower surface of the high-refraction unit HRP. The plurality of second contour lines OL2 may each overlap with the plurality of first contour lines OL1, respectively, or surround the plurality of first contour lines OL1, respectively.

A distance between each of the plurality of second contour lines OL2 and its pixel axis PXX may be a second distance D2. The second distance D2 shown in FIG. 9 may be same as the second distance D2 shown in FIG. 7.

The plurality of third contour lines OL3 may each define a planar shape of the medium-refraction unit MRP shown in FIG. 7. The plurality of third contour lines OL3 may each define a shape of the lower surface of the medium-refraction unit MRP. The plurality of third contour lines OL3 may each surround the plurality of first contour lines OL1, respectively. In addition, the plurality of third contour lines OL3 may each surround the plurality of second contour lines OL2, respectively.A distance between each of the plurality of third contour lines OL3 and its pixel axis PXX may be a third distance D3. The third distance D3 shown in FIG. 9 may be same as the third distance D3 shown in FIG. 7.

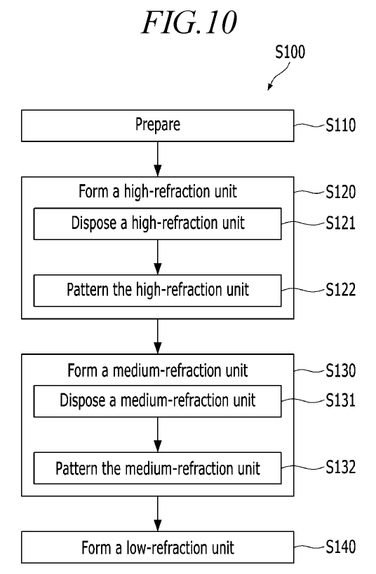

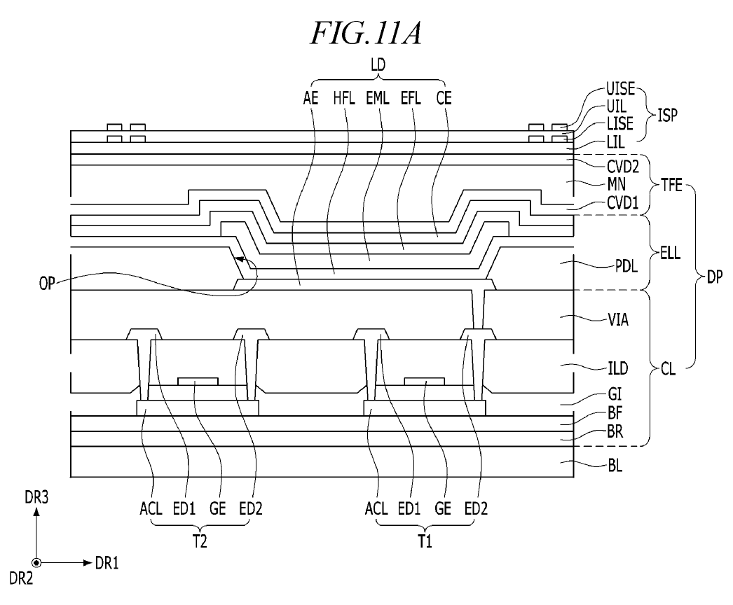

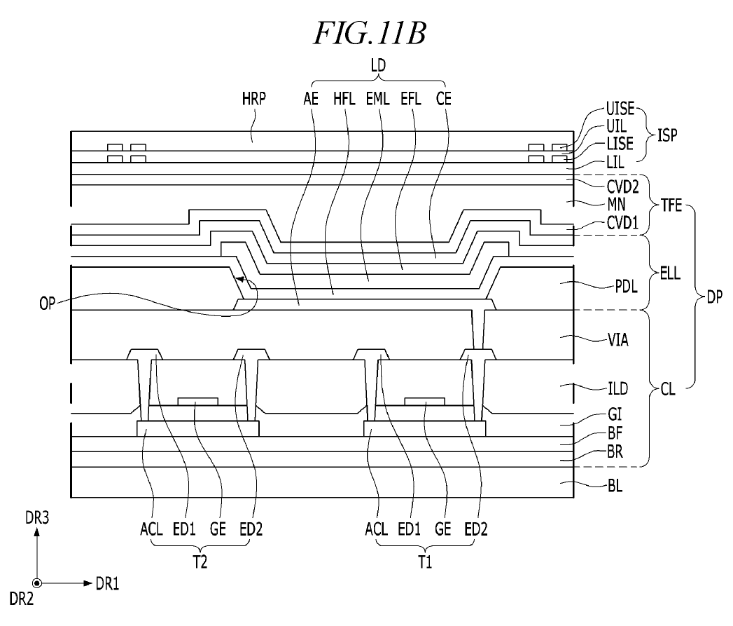

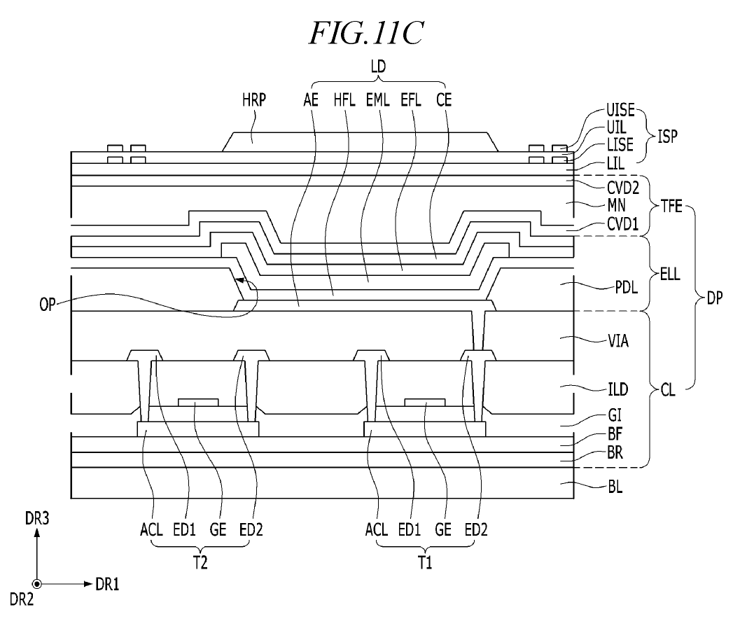

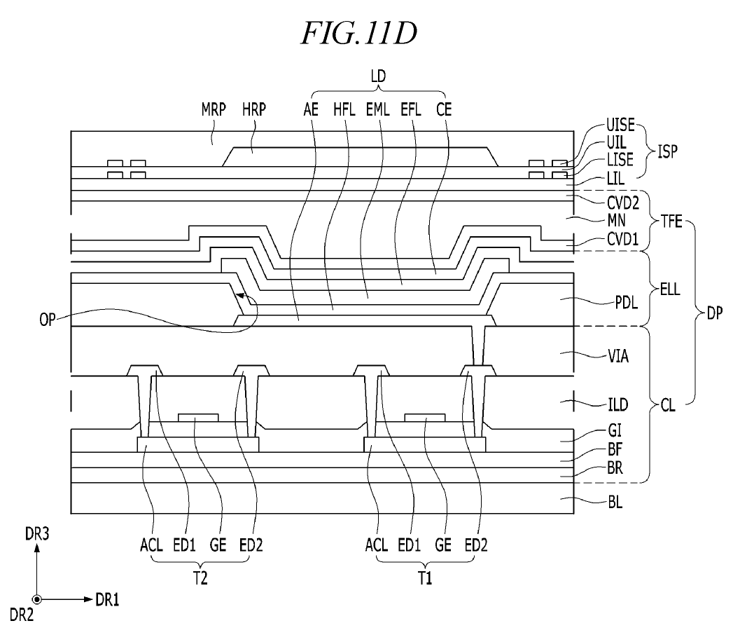

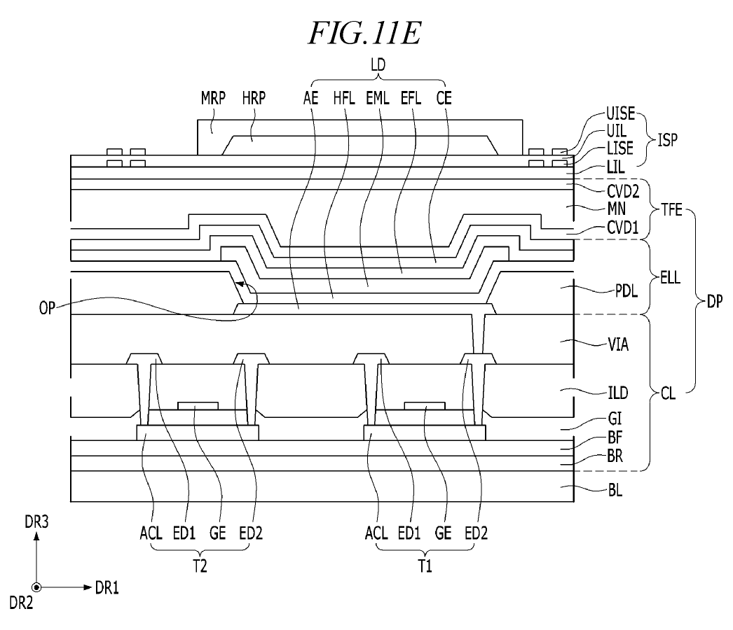

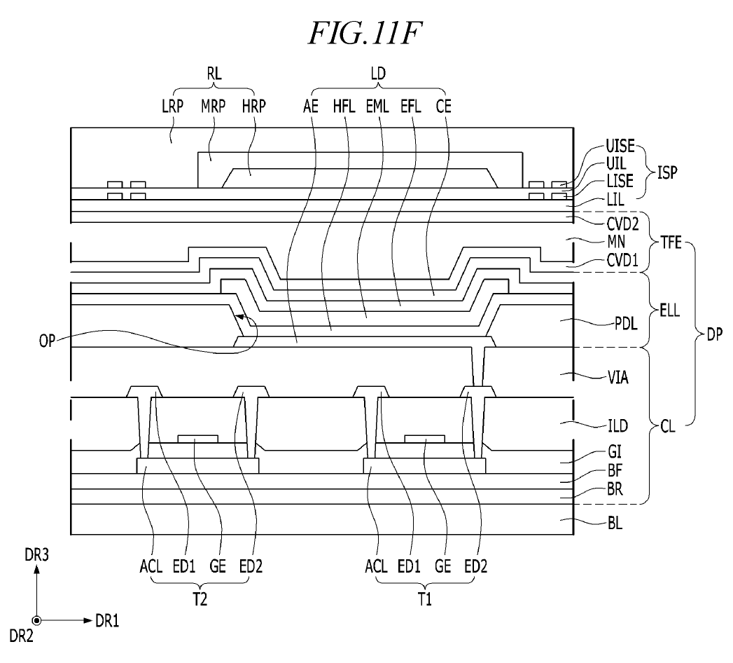

FIG. 10 is a flow chart of a method of manufacturing a display module S100 according to an embodiment of the present disclosure. FIGS. 11A through FIG. 11F are cross-sectional views of display module as the method of manufacturing the display module S100 proceeds through a series of steps according to an embodiment of the present disclosure.

Referring to FIG. 10 and FIG. 11A to FIG. 11F, a method of manufacturing an electronic device according to an embodiment of the present disclosure is described. Same figure refences are used for the components described with references to FIG. 1A through FIG. 9, and detailed descriptions thereof will be omitted.

Referring to FIG. 10, a method of manufacturing an electronic device S100 according to the present disclosure may include preparing S110, forming a high-refraction unit S120, forming a medium-refraction unit S130, and forming a low-refraction unit S140.

Referring to FIG. 10 and FIG. 11A, in the preparing S110, a display panel DP or a display module DPM may be prepared.

Referring to FIG. 10, FIG. 11B, and FIG. 11C, in the forming a high-refraction unit S120, a high-refraction unit HRP may be formed. The forming a high-refraction unit S120 may include disposing a high-refraction unit S121 and patterning the high-refraction unit S122.

Referring to FIG. 10 and FIG. 11B, in the disposing a high-refraction unit S121, a high-refraction unit HRP may be disposed. In the disposing a high-refraction unit S121, the high-refraction unit HRP may be disposed flat on a disposition plane.

Referring to FIG. 10 and FIG. 11C, in the patterning the high-refraction unit S122, the high-refraction unit HRP may be patterned. In the patterning the high-refraction unit S122, the high-refraction unit HRP may be patterned through a photolithography process. Accordingly, a side may be formed on the high-refraction unit HRP.

In an embodiment of the present disclosure, in the forming a high-refraction unit S120, the high-refraction unit HRP may be disposed through an inkjet spray process. Accordingly, the high-refraction unit HRP may be disposed with a side formed. In addition, the disposed high-refraction unit HRP may be hardened to have a high-refraction unit HRP formed.

Referring to FIG. 10, FIG. 11D, and FIG. 11E, in the forming a medium-refraction unit S130, a medium-refraction unit MRP may be formed. The forming a medium-refraction unit S130 may include disposing a medium-refraction unit S131 and patterning the medium-refraction unit S132.

Referring to FIG. 10 and FIG. 11D, in the disposing a medium-refraction unit S131, a medium-refraction unit MRP may be disposed. In the disposing a medium-refraction unit S131, a medium-refraction unit MRP may be disposed flat on the disposition plane and the high-refraction unit HRP.

Referring to FIG. 10 and FIG. 11E, in the patterning the medium-refraction unit S132, the medium-refraction unit MRP may be patterned. In the patterning the medium-refraction unit S132, the medium-refraction unit MRP may be patterned through a photolithography process. Accordingly, a side may be formed on the medium-refraction unit MRP.

In an embodiment of the present disclosure, in the forming a medium-refraction unit S130, a medium-refraction unit MRP may be formed through an inkjet spray process. Accordingly, a medium-refraction unit MRP may be disposed with a side formed. In addition, the disposed medium-refraction unit MRP may be hardened to have a medium-refraction unit MRP formed.

Referring to FIG. 10 and FIG. 11F, in the forming a low-refraction unit S140, a low-refraction unit LRP may be formed. In the forming a low-refraction unit S140, a low-refraction unit LRP may be disposed through, for example, an inkjet spray process or a slit coating process. In addition, the disposed low-refraction unit LRP may be hardened to have a low-refraction unit LRP formed.

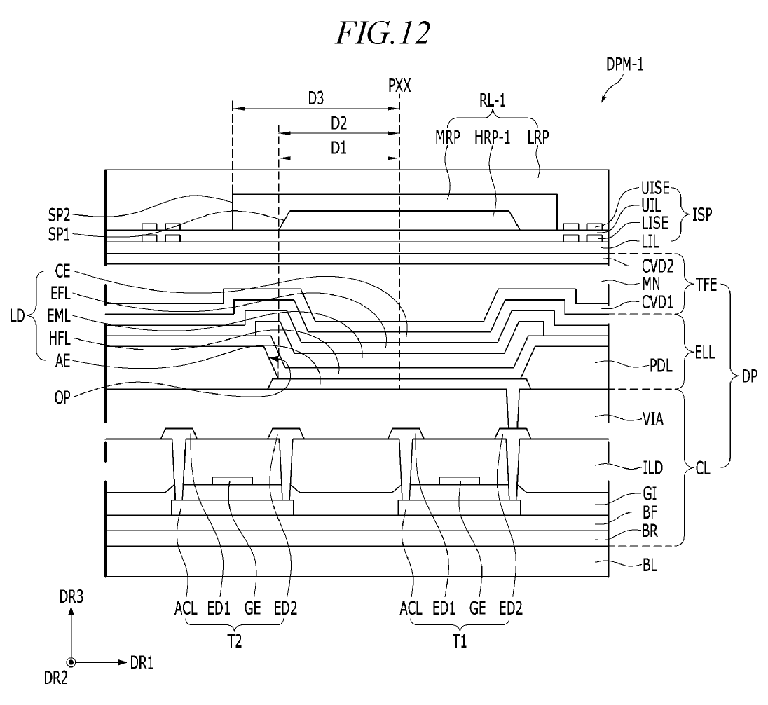

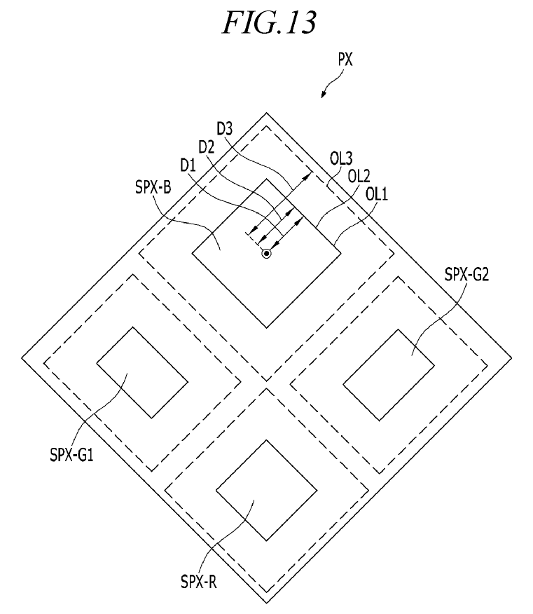

FIG. 12 is a cross-sectional view of a display module DPM-1 according to an embodiment of the present disclosure. FIG. 13 is a plan view of any one of a plurality of pixels PX according to an embodiment of the present disclosure.

Referring to FIG. 12 and FIG. 13, the first distance D1 and the second distance D2 may be same. Accordingly, a first contour line OL1 and a second contour line OL2-1 may make contact with each other. Furthermore, a planar shape of a pixel region PXA and a shape of a lower surface of the high-refraction unit HRP may be same.

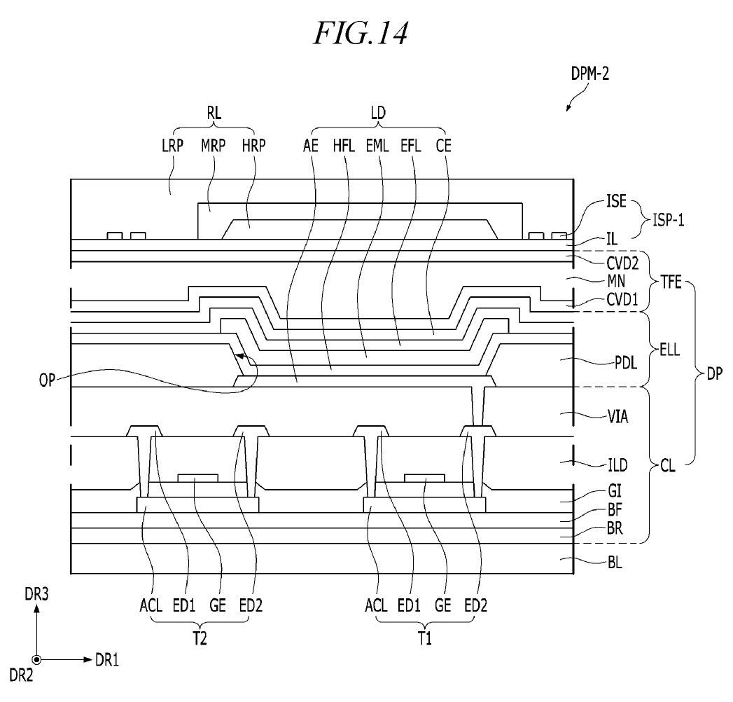

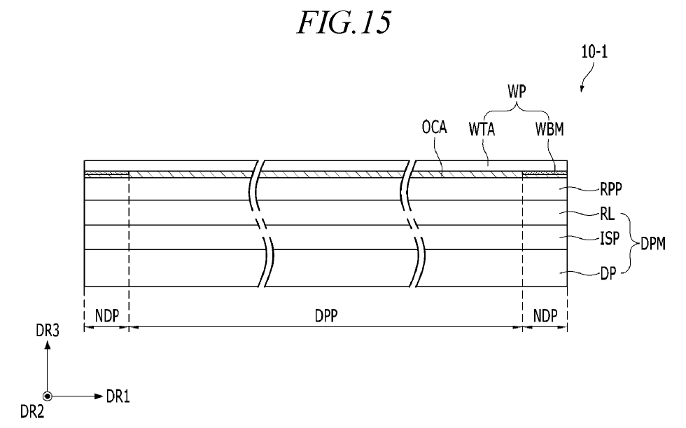

FIG. 14 is a cross-sectional view of a display module DPM-2 according to an embodiment of the present disclosure.

Referring to FIG. 14, the input sensor unit ISP-1 may include an inorganic insulating layer IL and an input sensor electrode ISE. The input sensor unit ISP-1 may include a self-capacitance type input sensor.

The inorganic insulating layer IL may be disposed on the encapsulation layer TFE. The inorganic insulating layer IL may be substantially same as the upper inorganic insulating layer UIL shown in FIG. 7. An upper surface of the inorganic insulating layer IL may be a disposition plane.

The input sensor electrode ISE may be disposed on the inorganic insulating layer IL. In case that an input tool approaches the input sensor electrode ISE, an electric field may be formed between the input sensor electrode ISE and the input tool.

FIG. 15 is a cross-sectional view of an electronic device 10-1 according to an embodiment of the present disclosure.

Referring to FIG. 15, a reflection protection member RPP may make direct contact with the display module DPM. In addition, the display module DPM may be attached to the reflection protection member RPP by the refraction layer RL.

The refraction layer RL may include a pressure-sensitive adhesive. Particularly, the low-refraction unit LRP of the refraction layer RL may include a pressure-sensitive adhesive. In addition, the low-refraction unit LRP may attach the display module DPM with the reflection protection member RPP.

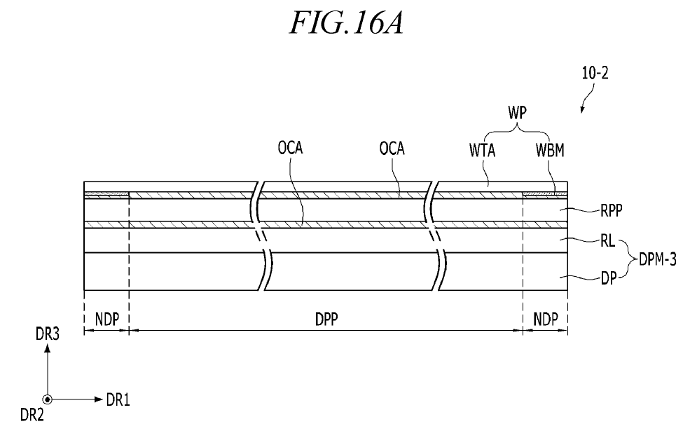

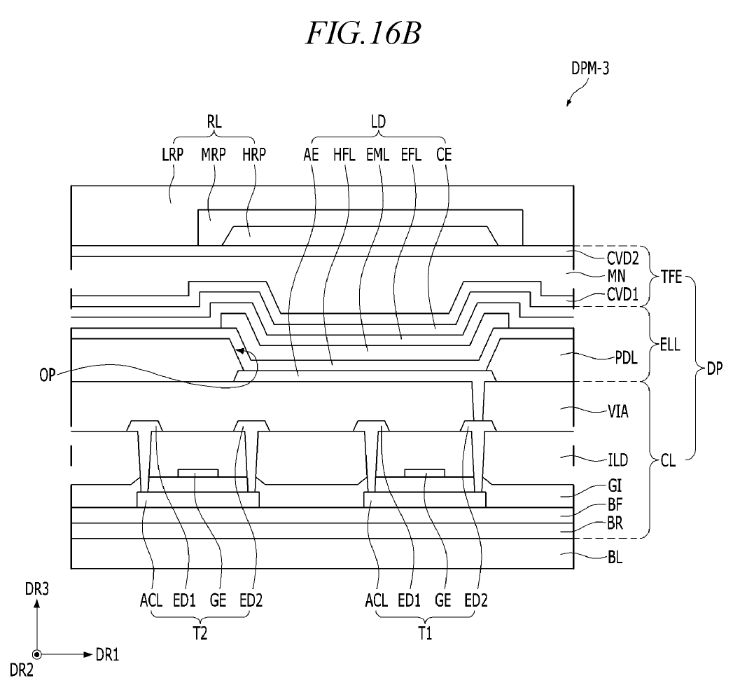

FIG. 16A is a cross-sectional view of an electronic device 10-2 according to an embodiment of the present disclosure. FIG. 16B is a cross-sectional view of a display module DPM-3 according to an embodiment of the present disclosure.

Referring to FIG. 16A and FIG. 16B, the display module DPM-3 may include a display panel DP and a refraction layer RL. The display module DPM-3 shown in FIG. 16A and FIG. 16B may have a configuration with the input sensor unit ISP omitted from the display module DPM shown in FIG. 5.

The refraction layer RL may be included in the display module DPM-3 regardless of presence of the input sensor unit ISP. In addition, an upper surface of the encapsulation layer TFE may be a pre-determined disposition plane.

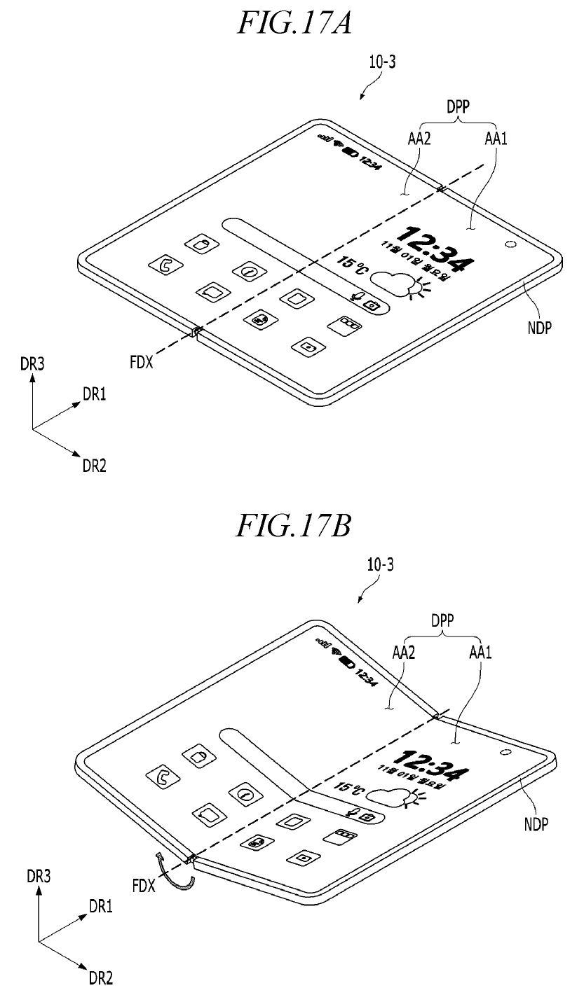

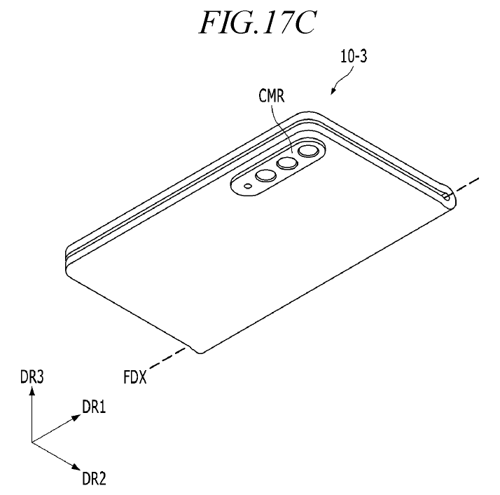

FIG. 17A, FIG. 17B, and FIG. 17C are illustrations of a foldable electronic device 10-3 according to an embodiment of the present disclosure.

Referring to FIG. 17A, FIG. 17B, and FIG. 17C, a display surface DPP and a non-display surface NDP may be defined in the electronic device 10-3. In addition, the electronic device 10-3 may include a camera unit CMR. The electronic device 10-3 may have an open mode in which the electronic device is unfolded based on a folding axis FDX, a bent mode in which the electronic device is partially bent based on the folding axis FDX, and a folded mode in which the electronic device is completely folded with respect to the folding axis FDX.

The display surface DPP may include a first region AA1 and a second region AA2. The first region AA1 may be positioned on one side with respect to the folding axis FDX. In addition, the second region AA2 may be positioned on another side with respect to the folding axis FDX.

The camera unit CMR may receive light. The camera unit CMR may overlap with the first region AA1. In addition, the camera unit CMR may face a direction opposite to a direction towards which the first region AA1 faces.

In FIG. 17A, the electronic device 10-3 may be in an open mode. In the open mode, both a front surface of the first region AA1 and a front surface of the second region AA2 may face the third direction DR3. In the open mode, one image may be shown over the first region AA1 and the second region AA2.

For example, a right portion of an image may be shown in the first region AA1, and a left portion of the image may be shown in the second region AA2. Therefore, a broader image may be visible to a user in the open mode.

In FIG. 17B, the electronic device 10-3 may be in a bent mode. In the bent mode, a front surface of the first region AA1 and a front surface of the second region AA2 may intersect with each other. Accordingly, in case that front light from the first region AA1 is viewed by a user of the electronic device 10-3, side light of the second region AA2 may be viewed by the user of the electronic device 10-3.

In the bent mode, different images may be shown in the first region AA1 and the second region AA2. For example, the first region AA1 may display a document, and the second region AA2 may display an input image. Therefore, the document shown in the first region AA1 may be drafted or edited through the input image shown in the second region AA2.

A rear surface of the second region AA2 may be positioned on a desk. In addition, an upper surface of the second region AA2 may face above. The first region AA1 may face a user. Accordingly, front light from the first region AA1 may be visible to a user of the electronic device 10-3. In addition, side light from the second region AA2 may be visible to a user of the electronic device 10-3.

Furthermore, the high-refraction unit HRP, the medium-refraction unit MRP, and the low-refraction unit LRP shown in FIG. 7 may be disposed to overlap with the second region AA2. As a result, luminance of side light of the second region AA2 may be increased. Accordingly, in the bent mode, a user may view the second region AA2 better.

In FIG. 17C, the electronic device 10-3 may be in a folded mode. In the folded mode, a front surface of the first region AA1 and a front surface of the second region AA2 may face each other. In addition, the front surface of the first region AA1 and the front surface of the second region AA2 may not be exposed. In the folded mode, the first region AA1 and the second region AA2 may not display an image.

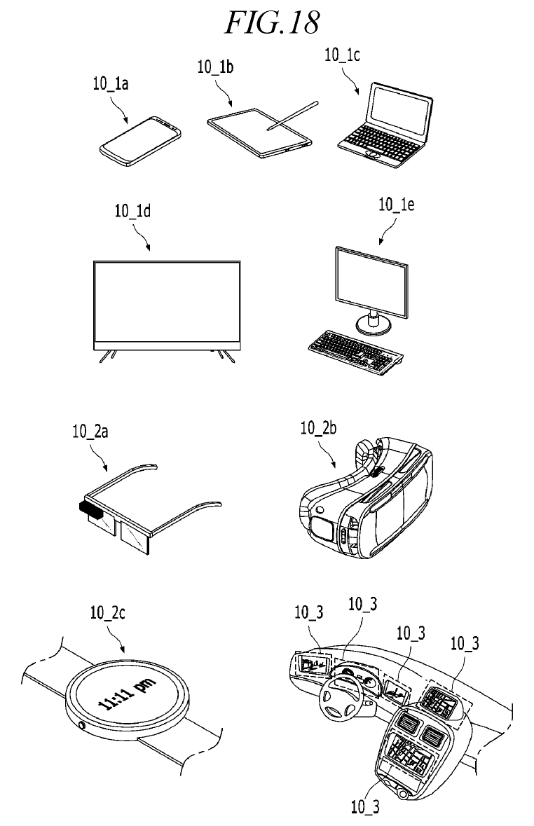

FIG. 18 illustrates electronic devices according to embodiments of the present disclosure.

Referring to FIG. 18, various electronic devices having display devices according to embodiments may include not only an image display electronic device, such as a smart phone 10_1a, a tablet PC 10_1b, a laptop 10_1c, a TV 10_1d, and a desk monitor 10_1e, but also a wearable electronic device including a display module, such as smart glasses 10_2a, a head mounted display 10_2b, and a smart watch 10_2c, and a vehicle electronic device 10_3 including a display module, such as a dashboard of an automobile, center fascia, and CID (Center Information Display) and a room mirror display disposed on an instrument panel.

While the present disclosure has been described with reference to embodiments thereof, it will be apparent to those of ordinary skill in the art that various changes and modifications may be made thereto without departing from the scope and spirit of the present disclosure as set forth in the following claims.

What is claimed is:

1. A display module comprising:
a base member;
a light-emitting diode disposed on the base member and configured to emit light;
an encapsulation layer configured to seal off the light-emitting diode;
a high-refraction unit disposed on the encapsulation layer, comprising a first side forming a first angle with a plane parallel to an upper surface of the encapsulation layer, and having a first refractive index;
a medium-refraction unit disposed on the high-refraction unit, comprising a second side forming a second angle with the plane parallel to the upper surface of the encapsulation layer, the second angle greater than the first angle, and having a second refractive index smaller than the first refractive index; and
a low-refraction unit disposed on the medium-refraction unit and having a third refractive index smaller than the second refractive index.

2. The display module of claim 1, wherein:
the medium-refraction unit covers the high-refraction unit; and
the low-refraction unit covers the medium-refraction unit.

3. The display module of claim 2,
wherein the high-refraction unit, the medium-refraction unit, and the low-refraction unit overlap with the light-emitting diode.

4. The display module of claim 3,
wherein the high-refraction unit, the medium-refraction unit, and the low-refraction unit make contact with a disposition plane.

5. The display module of claim 4, wherein:
the first refractive index is greater than or equal to 1.6 and smaller than or equal to 1.9;
the second refractive index is greater than 1.5 and smaller than 1.6; and
the third refractive index is greater than or equal to 1.2 and smaller than or equal to 1.5.

6. The display module of claim 4, wherein:
the first angle is greater than or equal to 60 degrees and smaller than or equal to 70 degrees; and
the second angle is greater than or equal to 88 degrees and smaller than or equal to 90 degrees.

7. The display module of claim 4, wherein:
an upper surface of the high-refraction unit and the disposition plane are spaced apart by a first vertical distance; and
an upper surface of the medium-refraction unit and the disposition plane are spaced apart by a second vertical distance, the second vertical greater than or equal to 1.5 times and less than or equal to 2.7 times of the first vertical distance.

8. The display module of claim 4, further comprising:
a pixel definition film disposed on the base member and comprising an inner surface for definition of an opening,
wherein a line extending in a direction perpendicular to the upper surface of the encapsulation layer in a center of the opening is defined as a pixel axis,
wherein the inner surface is spaced apart from the pixel axis by a first distance,
wherein one side of the high-refraction unit is spaced apart by a second distance greater than the first distance, and
wherein one side of the medium-refraction unit is spaced apart by a third distance greater than the second distance.

9. The display module of claim 8,
wherein the second distance is greater than or equal to 1 times and less than or equal to 1.11 times of the first distance.

10. The display module of claim 9,
wherein the third distance is greater than or equal to 1.65 times and less than or equal to 2.70 times of the first distance.

11. The display module of claim 3, further comprising:
an upper inorganic insulating layer disposed between the encapsulation layer and the high-refraction unit; and
an upper input sensor electrode disposed on the upper inorganic insulating layer.

12. The display module of claim 11, further comprising:
a lower inorganic insulating layer disposed between the encapsulation layer and the upper inorganic insulating layer; and
a lower input sensor electrode disposed between the lower inorganic insulating layer and the upper inorganic insulating layer.

13. An electronic device comprising:
a window member comprising a display surface; and
a display module configured to emit light on the window member, the display module comprising:
a base member;
a plurality of light-emitting diodes disposed on the base member, each configured to emit light;
an encapsulation layer configured to seal off the plurality of light-emitting diodes;
a high-refraction unit disposed on the encapsulation layer, comprising a first side forming a first angle with a plane parallel to an upper surface of the encapsulation layer, and having a first refractive index;
a medium-refraction unit disposed on the high-refraction unit, comprising a second side forming a second angle with the plane parallel to the upper surface of the encapsulation layer, having a second refractive index smaller than the first refractive index, the second angle greater than the first angle; and
a low-refraction unit disposed on the medium-refraction unit and having a third refractive index smaller than the second refractive index.

14. The electronic device of claim 13, wherein:
the medium-refraction unit covers the high-refraction unit;
the low-refraction unit covers the medium-refraction unit; and
the high-refraction unit, the medium-refraction unit, and the low-refraction unit overlaps with at least one of the plurality of light-emitting diodes.

15. The electronic device of claim 14,
wherein the high-refraction unit, the medium-refraction unit, and the low-refraction unit make contact with a disposition plane.

16. The electronic device of claim 15, wherein:
the low-refraction unit comprises a pressure-sensitive adhesive; and
the low-refraction unit is configured to attach the display module with another component.

17. The electronic device of claim 15,
wherein the disposition plane comprises a first region where a portion of the plurality of light-emitting diodes emit light, and a second region where another portion of the plurality of light-emitting diodes emit light,
wherein the high-refraction unit, the medium-refraction unit, and the low-refraction unit are disposed to overlap with the second region, and
wherein luminance of light emitted from the second region and having a viewing angle of 45 degrees is greater than luminance of light emitted from the first region and having a viewing angle of 45 degrees.

18. The electronic device of claim 17, wherein:
the first region is positioned on a flat surface, and
the second region is positioned on a curved surface.

19. The electronic device of claim 17, further comprising a camera unit configured to receive light and having a folded mode in which the electronic device is folded with respect to a folding axis and an open mode in which the electronic device is open with respect to the folding axis,
wherein the first region is positioned on one side with respect to the folding axis,
wherein the second region is positioned on another side with respect to the folding axis, and
wherein the camera unit overlaps with the first region and does not overlap with the second region in the open mode.

20. A method of manufacturing a display module, the method comprising:
preparing a display panel comprising a base member, a light-emitting diode disposed on the base member, and an encapsulation layer configured to seal off the light-emitting diode;
forming a high-refraction unit disposed on the encapsulation and comprising first sides forming a first angle with a plane parallel to an upper surface of the encapsulation layer and having a first refractive index;
forming a medium-refraction unit disposed on the high-refraction unit, comprising a second side forming a second angle with the plane parallel to the upper surface of the encapsulation layer, and having a second refractive index smaller than the first refractive index, the second angle greater than the first angle; and
forming a low-refraction unit disposed on the medium-refraction unit and having a third refractive index smaller than the second refractive index.
